(19) United States
(12) Patent Application Publication
(10) Pub. No.: US 2019/0177230 A1
(43) Pub. Date: Jun. 13, 2019

(54) OXIDE SINTERED BODY AND SPUTTERING TARGET, AND METHODS FOR MANUFACTURING SAME

(71) Applicant: KOBELCO RESEARCH INSTITUTE, INC., Kobe-shi, Hyogo (JP)

(72) Inventors: Yuki TAO, Takasago-shi (JP); Yasuo NAKANE, Takasago-shi (JP); Hideo HATA, Takasago-shi (JP)

(73) Assignee: KOBELCO RESEARCH INSTITUTE, INC., Kobe-shi Hyogo (JP)

(21) Appl. No.: 16/092,400

(22) PCT Filed: Feb. 9, 2017
(86) PCT No.: PCT/JP2017/004821

§ 371 Date: Oct. 9, 2018

(30) Foreign Application Priority Data
Apr. 19, 2016 (JP) 2016-083840
Jan. 19, 2017 (JP) 2017-007850

(51) Int. Cl. C04B 35/453; C23C 14/34

(52) U.S. Cl. CPC C04B 35/453; C23C 14/3414; C04B 2235/3284; C04B 35/645; C04B 2235/3293; C04B 2235/786; C04B 2235/3286

(57) ABSTRACT

Disclosed is an oxide sintered body, wherein contents of zinc, indium, gallium and tin relative to all metal elements satisfy the following inequality expressions: 40 atomic %≤[Zn]≤55 atomic %, 20 atomic %≤[In]≤40 atomic %, 5 atomic %≤[Ga]≤15 atomic %, and 5 atomic %≤[Sn]≤20 atomic %, where the contents (atomic %) of zinc, indium, gallium and tin relative to all metal elements excluding oxygen are respectively taken as [Zn], [In], [Ga] and [Sn], wherein the oxide sintered body has a relative density of 95% or more, and wherein the oxide sintered body includes, as a crystal phase, 5 to 20 volume % of InGaZn₂ O₅.

### TECHNICAL FIELD

The present disclosure relates to an oxide sintered body and a sputtering target, which are used when oxide semiconductor thin films of thin-film transistors (TFTs) to be used in display devices such as liquid crystal displays and organic EL displays are deposited by a sputtering method, and methods for manufacturing the oxide sintered body and the sputtering target.

### BACKGROUND ART

Amorphous (noncrystalline) oxide semiconductor thin films for use in TFTs have higher carrier mobility and larger optical band gaps and can be deposited at lower temperatures, as compared with general amorphous silicon (a-Si) thin films. Therefore, the amorphous oxide semiconductors are expected to be applied to next-generation displays which are required to have large sizes and high resolutions and to achieve high-speed drive, and applied to resin substrates having low heat resistance. As oxide semiconductors suitable for these applications, In-containing amorphous oxide semiconductors have been proposed. For example, In—Ga—Zn-based oxide semiconductors have been attracting attention.

For formation of the oxide semiconductor thin films mentioned above, a sputtering method is preferably used, in which a sputtering target (hereinafter sometimes referred to as “a target material”) made of a material having the same composition as that of the thin film is subjected to sputtering.

If abnormal discharge occurs during sputtering, the target material may undergo cracking. To suppress cracking, of the target material, it is studied to adjust the content of a crystal phase in the target material (e.g., Patent Documents 1 to 4).

Patent Document 1 discloses a target material composed of an In—Ga—Zn—Sn-based oxide sintered body in which the ratio of an InGaZn₂ O₅ phase as a main phase is controlled to 3% or less.

Patent Document 2 discloses a target material composed of an In—Ga—Sn-based oxide sintered body in which the ratio of an InGaO₃ phase is controlled to 0.05% or more.

Patent Document 3 discloses a target material composed of an In—Ga—Sn-based oxide sintered body in which the ratio of a Ga₃ InSn₅ O_{1 6} phase is controlled to 0.02% or more and 0.2% or less.

Patent Document 4 discloses a target material composed of an In—Ga—Sn-based oxide sintered body in which the ratio of a Ga₃ InSn₅ O_{1 6} phase is controlled to 0.02% or more and 0.2% or less.

### PRIOR ART DOCUMENT

### Patent Document

Patent Document 1: JP 2014-58415 A

Patent Document 2: JP 2015-127293 A

Patent Document 3: JP 2015-166305 A

Patent Document 4: JP 2011-252231 A

### DISCLOSURE OF THE INVENTION

### Problems to be Solved by the Invention

To further improve properties of the semiconductor thin film or to impart different properties, there has been studied an In—Ga—Zn—Sn-based oxide semiconductor thin film in which each content of indium, gallium, zinc and tin in the thin film is changed. To form such oxide semiconductor thin film, a target material provided with an In—Ga—Zn—Sn-based oxide sintered body having the same composition as that of the objective oxide semiconductor thin film is used.

Patent Document 1 discloses the target material of the In—Ga—Zn—Sn-based oxide sintered body. However, when the content of each element in the target material is different from that of Patent Document 1, even if the ratio of the InGaZn₂ O₅ phase was controlled to 3% or less, cracking of the target could not be suppressed in some cases.

The embodiment of the present invention has been made in light of the above circumstances, and a first object thereof is to provide an In—Ga—Zn—Sn-based oxide sintered body for use in a sputtering target, which is suitable for manufacturing an In—Ga—Zn—Sn-based oxide semiconductor thin film and can suppress the occurrence of cracking when the oxide sintered body containing a specific amount of each element is bonded on a backing plate.

A second object according to the embodiment of the present invention is to provide a method for manufacturing the oxide sintered body mentioned above.

A third object according to the embodiment of the present invention is to provide a sputtering target using the oxide sintered body mentioned above.

A fourth object according to the embodiment of the present invention is to provide a method for manufacturing a sputtering target.

### Means for Solving the Problems

The inventors have intensively studied so as to solve the above problems and found that the above problems can be solved by including the specific content of a crystal phase, especially InGaZn₂ O₅ in an oxide sintered body containing a predetermined amount of oxides of zinc, indium, gallium and tin, thus completing the embodiment of the present invention.

The oxide sintered body according to the embodiment of the present invention is an oxide sintered body, wherein contents of zinc, indium, gallium and tin relative to all metal elements satisfy the following inequality expressions:

40 atomic %≤[Zn]≤55 atomic %,

20 atomic %≤[In]≤40 atomic %,

5 atomic %≤[Ga]≤15 atomic %, and

5 atomic %≤[Sn]≤20 atomic %,

where the contents (atomic %) of zinc, indium, gallium and tin relative to all metal elements excluding oxygen are respectively taken as [Zn], [In], [Ga] and [Sn],

wherein the oxide sintered body has a relative density of 95% or more, and

wherein the oxide sintered body comprises, as a crystal phase, 5 to 20 volume % of InGaZn₂ O₅.

It is preferable that pores in the oxide sintered body have a maximum equivalent circle diameter of 3 μm or less.

It is preferable that a relative ratio of an average equivalent circle diameter to the maximum equivalent circle diameter of pores in the oxide sintered body is 0.3 or more and 1.0 or less.

In the above oxide sintered body, when [Zn]/[In] is more than 1.75 and less than 2.25,

it is preferable to further include, as a crystal phase:

30 to 90 volume % of Zn₂ SnO₄, and

1 to 20 volume % of InGaZnO₄.

In the above oxide sintered body, when [Zn]/[In] is less than 1.5,

it is preferable to further include, as a crystal phase, 30 to 90 volume % of In₂ O₃.

It is preferable that the oxide sintered body further includes, as a crystal phase, more than 0 volume % and 10 volume % or less of InGaZn₃ O₆.

The above oxide sintered body preferably has a crystal grain size of 20 μm or less, and particularly preferably has the crystal grain size of 5 μm or less.

It is preferable that the above oxide sintered body has a resistivity of 1 Ω·cm or less.

In the sputtering target according to the embodiment of the present invention, the above oxide sintered body is fixed on a backing plate using a bonding material.

The method for manufacturing an oxide sintered body of the embodiment of the present invention includes:

preparing a mixed powder containing zinc oxide, indium oxide, gallium oxide and tin oxide at a predetermined ratio, and

sintering the mixed powder into a predetermined shape.

In the above manufacturing method, the step of sintering may include retaining the mixed powder at a sintering temperature of 900 to 1,100° C. for 1 to 12 hours in a state of applying a surface pressure of 10 to 39 MPa to the mixed powder in a mold.

At this time, it is preferable that an average temperature rising rate to the sintering temperature is 600° C./hour or less in the step of sintering.

The above manufacturing method further includes preforming the mixed powder after the step of preparing the mixed powder and before the step of sintering,

wherein the step of sintering may include retaining a preformed molded body at a sintering temperature of 1,450 to 1,550° C. for 1 to 5 hours under normal pressure. At this time, it is preferable that an average temperature rising rate to the sintering temperature is 100° C./hour or less in the step of sintering.

The method for manufacturing a sputtering target according to the embodiment of the present invention includes: bonding the above oxide sintered body or the oxide sintered body obtained by the above manufacturing method on a backing plate using a bonding material.

### Effects of the Invention

According to the embodiment of the present invention, it is possible to provide an oxide sintered body capable of suppressing the occurrence of cracking when bonding on a backing plate, and a sputtering target using said oxide sintered body, and methods for manufacturing the oxide sintered body and the sputtering target.

### BRIEF DESCRIPTION OF THE DRAWINGS

FIG. 1 is a schematic cross-sectional view of a sputtering target according to the embodiment of the present invention.

FIG. 2 is a secondary electron image of an oxide sintered body.

### MODE FOR CARRYING OUT THE INVENTION

### <Oxide Sintered Body>

First, the oxide sintered body according to the embodiment of the present invention will be described in detail.

The oxide sintered body according to the embodiment of the present invention includes oxides of zinc, indium, gallium and tin. To manufacture a sputtering target capable of forming an oxide semiconductor thin film having excellent effect on TFT properties, there is a need to appropriately control the content of metal elements in in the oxide sintered body to be used for the sputtering target and the content of a crystal phase, respectively.

Thus, the oxide sintered body according to the embodiment of the present invention is an oxide sintered body, wherein contents of zinc, indium, gallium and tin relative to all metal elements satisfy the following inequality expressions:

40 atomic %≤[Zn]≤55 atomic %,

20 atomic %≤[In]≤40 atomic %,

5 atomic %≤[Ga]≤15 atomic %, and

5 atomic %≤[Sn]≤20 atomic %,

where the contents (atomic %) of zinc, indium, gallium and tin relative to all metal elements excluding oxygen are respectively taken as [Zn], [In], [Ga] and [Sn],

wherein the oxide sintered body has a relative density of 95% or more, and

wherein the oxide sintered body includes, as a crystal phase, 5 to 20 volume % of InGaZn₂ O₅.

“All metal elements excluding oxygen included in the oxide sintered body” are zinc, indium, gallium and tin, and can further include metal impurities that are inevitably mixed during manufacturing.

Since inevitable metal impurities are included in a trace amount, they hardly exert an influence on defining the ratio of metallic elements in the oxide sintered body. Therefore, “all metal elements excluding oxygen included in the oxide sintered body” are substantially zinc, indium, gallium and tin.

That is, in the present specification, when each of contents of zinc, indium, gallium and tin in the oxide sintered body is represented by the number of atoms, the content of zinc relative to the total amount of these contents (total number of atoms) is “[Zn]”, the content of indium relative to the total amount thereof is “[In]”, the content of gallium relative to the total amount thereof is “[Ga]” and the content of tin relative to the total amount thereof is “[Sn]”. Thus, [Zn]+[In]+[Ga]+[Sn]=100 atomic %. The content of each element is controlled so that the content (atomic %) ([Zn], [In], [Ga] and [Sn]) of each element of zinc, indium, gallium and tin thus defined satisfy a predetermined range.

The content (atomic %) of each element of zinc, indium, gallium and tin will be described in detail below. The content of each element is set mainly taking properties of the oxide semiconductor thin film to be deposited using the sputtering target into consideration.

### Content of Zinc: 40 Atomic %≤[Zn]≤55 Atomic %

Zinc improves the stability of the amorphous structure of the oxide semiconductor thin film. The content of zinc preferably satisfies the following inequality expression: 42 atomic %≤[Zn]≤54 atomic %, and more preferably satisfies the following inequality expression: 44 atomic %≤[Zn]≤53 atomic %.

Content of Indium: 20 atomic %≤[In]≤40 atomic %

Indium improves the carrier mobility of the oxide semiconductor thin film. The content of indium preferably satisfies the following inequality expression: 21 atomic %≤[In]≤39 atomic %, and more preferably satisfies the following inequality expression: 22 atomic %≤[In]≤38 atomic %.

Content of Gallium: 5 atomic %≤[Ga]≤15 atomic

Gallium improves the light stress reliability, i.e. improves the threshold bias shift of the oxide semiconductor thin film. The content of gallium preferably satisfies the following inequality expression: 6 atomic %≤[Ga]≤14 atomic %, and more preferably satisfies the following inequality expression: 7 atomic %≤[Ga]≤13 atomic %.

Content of Tin: 5 atomic %≤[Sn]≤20 atomic %

Tin improves the etchant resistance of the oxide semiconductor thin film. The content of tin preferably satisfies the following inequality expression: 6 atomic %≤[Sn]≤22 atomic %, and more preferably satisfies the following inequality expression: 7 atomic %≤[Sn]≤20 atomic %.

[Sn]/[Ga]: more than 0.5 and less than 2.5

[Sn]/[Ga] provides an indication of the content of InGaZn₃ O₆. [Sn]/[Ga] is preferably more than 0.5 and less than 2.5. If [Sn]/[Ga] is less than 0.5, the content of InGaZn₃ O₆ exceeds 20 volume %. If [Sn]/[Ga] is 2.5 or more, the content of InGaZn₃ O₆ becomes 0 volume %.

The oxide sintered body includes oxides of zinc, indium, gallium and tin. Specifically, the oxide sintered body includes a Zn₂ SnO₄ phase, an InGaZnO₄ phase, an InGaZn₂ O₅ phase, an InGaZn₃ O₆ phase, an In₂ O₃ phase and a SnO₂ phase as a constituent phase. The oxide sintered body may further include impurities such as oxides and the like which are inevitably mixed or produced during manufacturing.

Particularly in the embodiment of the present invention, it is possible to effectively suppress cracking of the oxide sintered body by including the InGaZn₂ O₅ phase at a predetermined ratio.

The ratio of the crystal phase can be determined by analyzing X-ray diffraction spectrum of the oxide sintered body. On the premise that the above-mentioned crystal phases (i.e., Zn₂ SnO₄ phase, InGaZnO₄ phase, InGaZn₂ O₅ phase, InGaZn₃ O₆ phase, In₂ O₃ phase and SnO₂ phase) exist, peaks of the X-ray diffraction spectrum are assigned to a specific crystal surface of those six crystal phases. One peak is selected from a plurality of peaks assigned to each crystal phase, and then the peak intensity of the selected peak is measured. Six measured values of the peak intensity are obtained from six crystal phases, and the six measured values are converted into the strongest peak intensity of each crystal phase. The ratio of the converted value of each, crystal phase to the value (total value) obtained by summing up the six converted values is determined. Each ratio is taken as the ratio (content: volume %) of each crystal phase included in the oxide crystal body. That is, in the present specification, when six converted values of the peak intensity obtained from each crystal phase are summed up and the total value thereof is taken as 100%, the ratio (%) of each converted value corresponding to each crystal phase is used as the content (volume) of each crystal phase.

As mentioned above, in the present specification, when the content (volume %) of the crystal phase is calculated, only the Zn₂ SnO₄ phase, the InGaZnO₄ phase, the InGaZn₂ O₅ phase, the InGaZn₃ O₆ phase, the In₂ O₃ phase and the SnO₂ phase are taken into consideration. Actually, crystal phases other than the above-mentioned crystal phases can also be included, but they do not affect the effects (prevention of cracking of the oxide sintered body) according to the embodiment of the present invention. Therefore, in the embodiment of the present invention, only the above-mentioned six crystal phases are taken into consideration so as to obtain the effect of preventing cracking of the oxide sintered body.

The content (volume %) of each crystal phase, which can be included in the oxide sintered body, will be described in detail. It is to be noted that the unit of the content ratio (volume %) of the crystal phase may be simply referred to as “%”.

InGaZn₂ O₅: 5 to 20 volume %

InGaZn₂ O₅ has the pinning effect between grains. Inclusion of InGaZn₂ O₅ enables suppression of the crystal grain size growth to increase the material strength, thus making it possible to suppress cracking of the oxide sintered body when bonding on a backing plate.

If the content of InGaZn₂ O₅ is less than 5 volume %, because of insufficient material strength, cracking of the oxide sintered body is likely to occur. If the content exceeds 30 volume %, since the resistivity increases, abnormal discharge might be induced. Therefore, when including 5 volume % of InGaZn₂ O₅, it is possible to sufficiently exert the effect of preventing cracking of the oxide sintered body. Meanwhile, if the content of InGaZn₂ O₅ is too large, the equilibrium state of the main phase is broken leading to deterioration of the discharge stability, so that the content is set at 30 volume % or less.

The content of InGaZn₂ O₅ is preferably 5 to 20 volume %, and more preferably 5 to 15 volume %.

InGaZn₃ O₆: more than 0 volume % and 10 volume % or less

Like InGaZn₂ O₅, InGaZn₃ O₆ has the pinning effect between grains. When including InGaZn₃ O₆, in addition to InGaZn₂ O₅, the pinning effect can be further improved. Therefore, it is possible to further suppress cracking of the oxide sintered body when bonding on a backing plate.

InGaZn₃ O₆ is preferably included in the amount of 0.5 to 8 volume %, and more preferably 1 to 6 volume %.

When the content of the crystal phase is changed by the content of the element, it is possible to improve the effect of suppressing cracking of the oxide sintered body.

For example, each content of Zn₂ SnO₄, InGaZnO₄ and In₂ O₃ preferably varies depending on the ratio of [Zn]/[In].

Zn₂ SnO₄ and In₂ O₃ have the effect of contributing to an improvement in relative density and reduction in resistivity. The discharge stability can be improved.

Like InGaZn₂ O₅ and InGaZn₃ O₆, InGaZnO₄ has the pinning effect between grains. When including InGaZnO₄, in addition to InGaZn₂ O₅, the pinning effect can be further improved. Therefore, it is possible to further suppress cracking of the oxide sintered body when bonding on a backing plate.

If [Zn]/[In] is more than 1.75 and less than 2.25, it is preferable that Zn₂ SnO₄ is included in the amount of 30 to 90 volume % and InGaZnO₄ is included in the amount of 1 to 20 volume %.

If [Zn]/[In] is less than 1.5, it is preferable that In₂ O₃ is included in the amount of 30 volume % or more.

The relative density of the oxide sintered body is preferably 95% or more. Whereby, the strength of the oxide sintered body increases, thus making it possible to suppress cracking of the oxide sintered body when bonding on a backing plat. The relative density is more preferably 97% or more, and still more preferably 99% or more.

The relative density as used herein is determined in the following manner.

An oxide sintered body prepared as a measuring sample, is cut at any position in a thickness direction and the cut surface at any position is mirror-polished. Next, a photograph was taken at a magnification of 1,000 times using a scanning electron microscope (SEM), and the area ratio (%) of pores in the region of a 100 μm square is measured and taken as “porosity (%)”. In the same sample, the porosity was measured in the cut surface at 20 positions in the same manner, and the average of the porosity obtained by the measurement of 20 times was taken as the average porosity (%) of the sample. The value determined by [100−average porosity] was taken as “relative density (%)” as used herein.

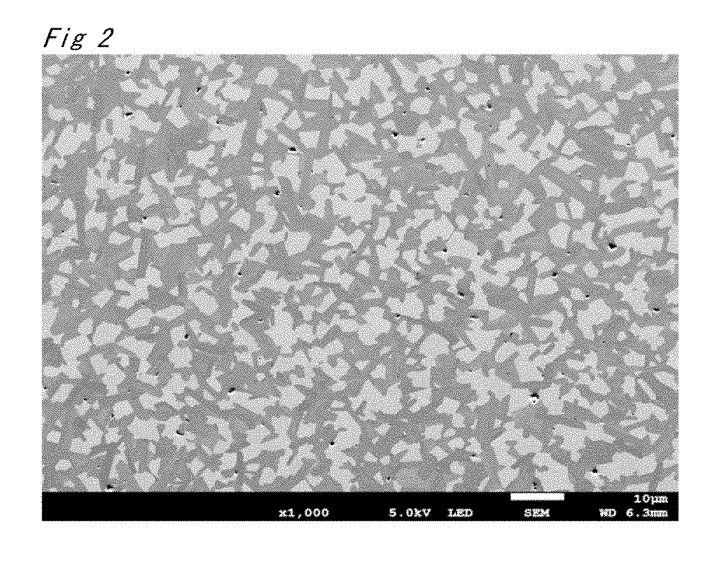

In FIG. 2, an example of a secondary electron image (magnification: 1,000 times) of the oxide sintered body is shown. In FIG. 2, black dot-shaped portions are pores. Pores can be easily identified from other metal structures in both the SEM micrograph and the secondary electron image.

Regarding the pores in the oxide sintered body, lower porosity as well as smaller pore size are preferable.

When a molded body including pores is sintered, small pores disappear by sintering, but large pores do not disappear and remain inside the oxide sintered body. In the pores in the oxide sintered body, the gas exists in a compressed state. Sn, Ga and the like in the molded body may be sometimes decomposed during sintering to form pores inside the oxide sintered body. Compressed gas may also exist inside the pores thus formed. When pores containing compressed gas exist in the oxide sintered body, the internal stress increases, leading to a decrease in mechanical strength and deterioration of the thermal shock resistance of the oxide sintered body.

Cracking of the oxide sintered bodies due to pores tends to increase as pores become larger. Therefore, the mechanical strength of the oxide sintered body is increased by making the size of the pores in the oxide sintered body smaller, thus making it possible to suppress cracking of the oxide sintered body. The internal stress can be sufficiently lowered by setting a maximum, circle equivalent diameter Dₘₐₓ of the pores at 3 μm or less. It is more preferable that the maximum equivalent circle diameter of the porosity is 2 μm or less.

The relative ratio of the average equivalent circle diameter Dₐᵥₑ (μm) to the maximum circle equivalent diameter Dₘₐₓ (μm) of the pores in the oxide sintered body is preferably 0.3 or more and 1.0 or less (i.e., 0.3≤Dₐᵥₑ/Dₘₐₓ≤1.0). When the relative ratio is 1.0, the pores have a circular shape, and as the relative ratio becomes smaller, the shape becomes flat elliptical.

When the shape of the pores is elliptical, the mechanical strength decreases as compared with the case of the circular shape and the oxide sintered body is easily broken. In particular, the tendency becomes prominent as the shape becomes flat elliptical. Therefore, the strength of the oxide sintered body can be increased by setting the relative ratio at 0.3 or more. It is more preferable that the relative ratio is 0.5 or more.

The maximum equivalent circle diameter and the average equivalent circle diameter of pores as used herein are determined in the following manner.

An oxide sintered body prepared as a measuring sample is cut at any position in a thickness direction and the cut surface at any position is mirror-polished. Next, a photograph was taken at an appropriate magnification (e.g., 1,000 times) using a scanning electron microscope (SEM), and the equivalent circle diameter of all pores in the region of a 100 μm square was determined. In the same sample, the equivalent circle diameter of all pores was determined in the cut surface at 20 positions in the same manner. The largest equivalent circle diameter among all the equivalent circle diameters obtained by the measurement of 20 times was taken as “maximum equivalent circle diameter of pores” of the oxide sintered body and the average of all the equivalent circle diameters was taken as “equivalent circle diameter of pores” of the oxide sintered body.

Refining of grains of the oxide sintered body enables enhancement of the effect of suppressing cracking of the oxide sintered body when bonding on a backing plate. The average crystal grain size of the grains is preferably 20 μm or less, whereby, the effect of prevention cracking of the oxide sintered body can be further improved. The average crystal grain size is more preferably 10 μm or less, still more preferably 8 μm or less, and particularly preferably 5 μm.

Meanwhile, there is no particular limitation on lower limit of the average crystal grain size. From the viewpoint of the balance between the refinement of the average crystal grain size and the production cost, preferable lower limit of the average crystal grain size is about 0.05 μm.

The average crystal grain size of grains is measured in the following manner.

An oxide sintered body prepared as a measuring sample is cut at any position in a thickness direction and the cut surface at any position is mirror-polished. Next, a photograph was taken at a magnification of 400 times using a scanning electron microscope (SEM). A straight line having a length of 100 μm is drawn in an arbitrary direction on the photograph thus taken, and the number (N) of grains existing on the straight line is determined. The value calculated from [100/N] (μm) is taken as “a crystal grain size on the straight line”. Furthermore, 20 straight lines each having a length of 100 μm are drawn on the photograph and the crystal grain sizes on the individual straight lines are calculated. Then, the value calculated from [sum of the crystal grain sizes on the individual straight lines/20] was taken as “an average crystal grain size of the oxide sintered body” as, used herein.

It is more preferable to appropriately control the particle size distribution, in addition to controlling of the average crystal grain size of grains of the oxide sintered body. In particular, since coarse grains having a crystal grain size more than 30 μm cause cracking of the oxide sintered body during bonding, it is preferable to use coarse grains as few as possible. The area ratio of the coarse grains having the crystal grain size of more than 30 μm is preferably 10% or less, more preferably 8% or less, still more preferably 6% or less, yet more preferably 4% or less, and most preferably 0%.

The area ratio of coarse grains having a crystal grain size of more than 30 μm is measured in the following manner.

When a straight line having a length of 100 μm is drawn in the measurement of “an average crystal grain size of grains”, grains having a length cut off on the straight line of 30 μm or more are taken as “coarse grains”. The length occupied by the coarse grains on the straight line having a length of 100 μm (i.e., length of the part crossing the grains of the straight line) is taken as the length L (μm). The value obtained by dividing L (μm) by 100 (μm) was taken as the ratio R (%) of the coarse grains on this straight line.

R(%)=(L(μm)/100(μm))×100(%)

When there are a plurality of coarse grains on the straight line having a length of 100 μm, the sum of the lengths of the parts crossing individual coarse grains is taken as L (μm) and the ratio R (%) of the coarse grains is determined.

The ratio R (%) of the coarse grains is determined for each of 20 straight lines drawn in the measurement of the average crystal grain size of the grains, and the average thereof was taken as the ratio of the coarse grains of the sintered body.

The resistivity of the oxide sintered body is preferably 1 Ω·cm or less, more preferably 10⁻¹ Ω·cm or less, and still more preferably 10⁻² Ω·cm or less. As mentioned below, the oxide sintered body is fixed on a backing plate to form a sputtering target. When using this sputtering target, abnormal discharge during sputtering can be suppressed by suppressing the resistivity of the oxide sintered body to a low level, leading to suppression of cracking of the oxide sintered body due to abnormal discharge. Whereby, it is possible to suppress the cost of deposition of an oxide semiconductor thin film using the sputtering target. Furthermore, since deposition failure due to abnormal discharge during sputtering can be suppressed, it is possible to manufacture an oxide semiconductor thin film that is uniform and has satisfactory properties.

For example, the manufacture of an oxide semiconductor thin film of TFT using the sputtering target in a manufacturing line for manufacturing a display device enables suppression of the manufacturing cost of TFT, leading to suppression of the manufacturing cost of the display device. It is also possible to form an oxide semiconductor thin film that exhibits satisfactory TFT properties, thus making it possible to manufacture a high-performance display device.

The resistivity of the oxide sintered body was measured by the four-point probe method. More specifically, the resistivity of the oxide sintered body can be measured using a known resistivity meter (e.g., Loresta GP, manufactured by Mitsubishi Chemical Analytech Co., Ltd.). It is to be noted that the resistivity as used herein refers to the value obtained by measuring at a distance between terminals of 1.5 mm. The resistivity was measured plural times (for example, 4 times) at different places, and the average thereof was taken as the resistivity of the oxide sintered body.

### <Sputtering Target>

Next, a sputtering target using an oxide sintered body will be described.

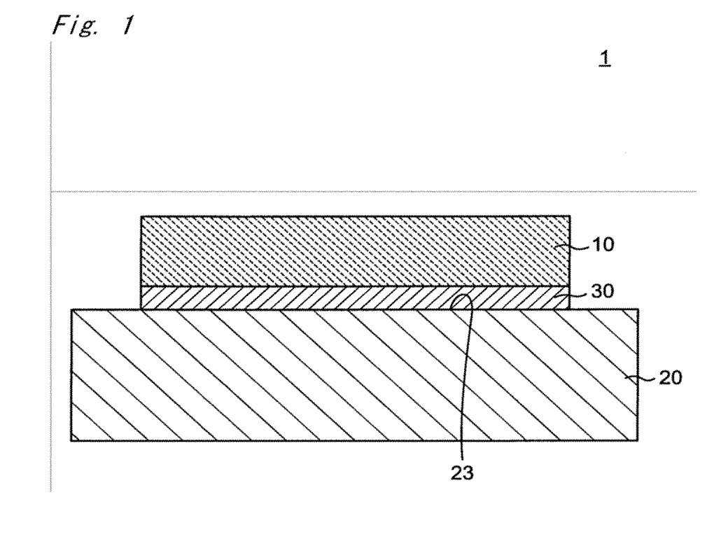

FIG. 1 is a schematic cross-sectional view of a sputtering target 1. The sputtering target 1 includes a backing plate 20 and an oxide sintered body 10 fixed on the backing plate 20 using a bonding material 30.

As the oxide sintered body 10, the oxide sintered body according to the embodiment of the present invention is used. Therefore, when bonding on the backing plate 20 using the bonding material 30, the oxide sintered body is less likely broken and the sputtering target 1 can be manufactured with good yield.

### <Manufacturing Method>

Next, the oxide sintered body and the method for manufacturing a sputtering target according to the embodiment of the present invention will be described.

The oxide sintered body according to the embodiment of the present invention can be obtained by sintering a mixed powder containing zinc oxide, indium oxide, gallium oxide and tin oxide. The sputtering target according to the embodiment of the present invention can be obtained by fixing the thus obtained oxide sintered body on a backing plate.

More specifically, the oxide sintered body is manufactured by the following steps (a) to (e) and the sputtering target is manufactured by the following steps (f) and (g):

step (a) of mixing and pulverizing powders of oxides,

step (b) of drying and granulating the thus obtained mixed powder,

step (c) of preforming the granulated mixed powder,

step (d) of degreasing the preformed molded body,

step (e) of sintering the degreased molded body to obtain an oxide sintered body,

step (f) of processing the thus obtained oxide sintered body, and

step (g) of bonding the thus processed oxide sintered body on a backing plate to obtain a sputtering target.

In the embodiment of the present invention, in the step (a), a mixed powder containing these oxides is prepared so that zinc, indium, gallium and tin are included at a predetermined ratio in the oxide sintered body finally obtained. In the step (e), the sintering conditions are controlled so that the crystal phase in the oxide sintered body is formed in an appropriate range. The steps (b) to (d) and (f) to (g) are not particularly limited as long as the oxide sintered body and the sputtering target can be manufactured, and it is possible to appropriately apply the steps that are usually used in the manufacture of the oxide sintered body and the sputtering target. Each step will be described in detail below, but the embodiment of the present invention is not limited to these steps.

### (Step (a) of Mixing and Pulverizing Powders of Oxides)

A zinc oxide powder, an indium oxide powder, a gallium oxide powder and a tin oxide powder are blended at a predetermined ratio, mixed and then pulverized. The purity of each raw material powder to be used is preferably about 99.99% or more. This is because the existence of a trace amount of impurity element might impair the semiconductor properties of the oxide semiconductor thin film.

The “predetermined ratio” of each raw material powder means the ratio so that contents of zinc, indium, gallium and tin relative to all metal elements excluding oxygen (zinc, indium, gallium and tin) included in the oxide sintered body obtained after sintering fall within the following ranges:

40 atomic %≤[Zn]≤55 atomic %,

20 atomic %≤[In]≤40 atomic %,

5 atomic %≤[Ga]≤15 atomic %, and

5 atomic %≤[Sn]≤20 atomic %

Usually, raw material powders may be blended so that contents of zinc, indium, gallium and tin relative to all metal elements excluding oxide included in the mixed powder after mixing the raw material powders (zinc oxide, indium oxide powder, gallium oxide powder and tin oxide powder) fall within the above ranges.

For mixing and pulverization, a ball mill or a beads mill is preferably used. A mixed powder can be obtained by charging raw material powders and water into a mill apparatus, and pulverizing and mixing the raw material powders. At this time, for the purpose of uniformly mixing the raw material powders, a dispersant may be added and mixed, and a binder may also be added and mixed so as to make it easy to form a molded body later.

It is possible to use, as balls and beads used in the ball mill and the beads mill (these are referred to as “media”), those made of zirconium oxide, nylon or alumina. It is possible to employ, as a pod to be used for the ball mill and the beads mill, a nylon pod, an alumina pod and a zirconia pod.

The mixing time in the ball mill or the beads mill is preferably 1 hour or more, more preferably 10 hours or more, and still more preferably 20 hours or more.

### (Step (b) of Drying and Granulating the Mixed Powder)

It is preferable that the mixed powder obtained in the step (a) is dried using, for example, a spray dryer and granulated.

### (Step (c) of Preforming the Granulated Mixed Powder)

It is preferable that the granulated mixed powder is charged into a die having a predetermined size and then preformed into a predetermined shape by applying a predetermined pressure (e.g., about 49 MPa to about 98 MPa) of pressure using a die press.

When sintering in the step (e) is performed by hot pressing, the step (c) may be omitted, and the mixed powder is charged into a sintering die and subjected to pressure sintering, whereby, a dense oxide sintered body can be manufactured. To make it easy to handle, the molded body may be placed in a sintering die and subjected to hot pressing after preforming in the step (c).

Meanwhile, when sintering in the step (e) is performed by pressureless sintering, a dense oxide sintered body can be manufactured by preforming in the step (c).

### (Step (d) of Degreasing the Preformed Molded Body)

When the dispersant and/or the binder is/are added to the mixed powder in the step (a), the molded body is preferably heated to remove the dispersant and the binder (i.e., degreasing). The heating conditions (heating temperature and retention time) are not particularly limited as long as the dispersant and the binder can be removed. For example, the molded body is retained in the air at a heating temperature of about 500° C. for about 5 hours.

In the step (a), when the dispersant and the binder were not used, the step (d) may be omitted.

When the step (c) is omitted, that is, when sintering is performed by hot pressing in the step (e) and the molded body is not formed, the mixed powder may be heated to remove the disperse the dispersant and the binder in the mixed powder (degreasing).

### (Step (e) of Sintering the Molded Body to Obtain Oxide Sintered Body)

The molded body after degreasing is sintered under predetermined sintering conditions to obtain an oxide sintered body. It is possible to use, as a sintering method, either hot pressing or pressureless sintering. Hot pressing is advantageous in that the crystal grain size of the obtained oxide sintered body can be reduced. Pressureless sintering is advantageous in that pressurizing equipment is unnecessary since there is no need to apply the pressure.

The sintering conditions will be described below for each of hot pressing and pressureless sintering.

### (i) Hot Pressing

In hot pressing, a molded body is placed in a sintering furnace in a state where the molded body is placed in a sintering die, and sintering is performed in a pressurized state. By sintering the molded body while applying the pressure to the molded body, a dense oxide sintered body can be obtained while suppressing the sintering temperature to a comparatively low level.

In hot pressing, a sintering die for pressurizing the molded body is used. It is possible to use, as a sintering die, either a die made of metal (metal die) or a die made of graphite (graphite die), depending on the sintering temperature. In particular, a graphite die excellent in heat resistance is preferable and it can withstand high temperatures of 900° C. or higher.

The pressure applied to the die is not particularly limited and the surface pressure (pressure to be applied) is preferably 10 to 39 MPa. If the pressure is too high, the sintering graphite die might be broken and large-sized press equipment is required. Meanwhile, if the pressure exceeds 39 MPa, the densification promoting effect of the sintered body is saturated, so that there is little benefit of pressurization at a pressure higher than the above pressure. Meanwhile, if the pressure is less than 10 MPa, densification of the sintered body does not easily proceed sufficiently. More preferable pressurization conditions are 10 to 30 MPa.

The sintering temperature is set at the temperature, at which sintering of the mixed powder in the molded body proceeds, or higher. For example, if sintering is performed under a surface pressure of 10 to 39 MPa, the sintering temperature is preferably 900 to 1,200° C.

If the sintering temperature is 900° C. or higher, sintering proceeds sufficiently and the density of the obtained oxide sintered body can be increased. The sintering temperature is more preferably 920° C. or higher, and still more preferably 940° C. or higher. If the sintering temperature is 1,200° C. or lower, the crystal grain size in the oxide sintered body can be reduced by suppressing the grain growth during sintering. The sintering temperature is more preferably 1,100° C. or lower, and still more preferably 1,000° C. or lower.

The time during which retention is made at a predetermined sintering temperature (retention time) is set at the time during which sintering of the mixed powder proceeds sufficiently and the density of the obtained oxide sintered body becomes the predetermined density or more. For example, if the sintering temperature is 900 to 1,200° C., the retention time is preferably 1 to 12 hours.

If the retention time is 1 hour or more, the structure in the oxide sintered body to be obtained can be made uniform. The retention time is more preferably 2 hours or more, and still more preferably 3 hours or more. If the retention time is 12 hours or less, it is possible to reduce the crystal grain size in the oxide sintered body by suppressing the grain growth during sintering. The retention time is more preferably 10 hours or less, and still more preferably 8 hours or less.

The average temperature rising rate to the sintering temperature can affect the size of grains in the oxide sintered body and the relative density of the oxide sintered body. The average temperature rising rate is preferably 600° C./hour or less, and since abnormal growth of the grains hardly occurs, the ratio of coarse grains can be suppressed.

If the average temperature rising rate is 600° C./hour or less, the relative density of the oxide sintered body after sintering can be increased. More preferably, the average temperature rising rate is 400° C./hour or less, and more preferably 300° C./hour or less.

The lower limit of the average temperature rising rate is not particularly limited, and is preferably 50° C./hour or more, and more preferably 100° C./hour or more, from the viewpoint of the productivity.

In the sintering step, the sintering atmosphere is preferably an inert gas atmosphere so as to suppress the oxidation and disappearance of the sintering graphite die. It is possible to apply, as a suitable inert atmosphere, for example, an atmosphere of an inert gas such as Ar gas or N₂ gas. For example, by introducing the inert gas into the sintering furnace, the sintering atmosphere can be adjusted. The pressure of the atmospheric gas is desirably an atmospheric pressure so as to suppress vaporization of metal having a high vapor pressure, and may be vacuum (i.e., pressure lower than the atmospheric pressure).

### (ii) Pressureless Sintering

In pressureless sintering, a molded body is placed in a sintering furnace and sintered under normal pressure. In pressureless sintering, the pressure is not applied during sintering and sintering hardly proceeds, so that sintering is usually performed at a sintering temperature higher than that in hot pressing.

The sintering temperature is not particularly limited as long as it is the temperature, at which sintering of the mixed powder in the molded body proceeds, or higher. For example, the sintering temperature can be set at 1,450 to 1,600° C.

If the sintering temperature is 1,450° C. or higher, sintering proceeds sufficiently and the density of the obtained oxide sintered body can be increased. The sintering temperature is more preferably 1,500° C. or higher, and still more preferably 1,550° C. or higher. If the sintering temperature is 1,600° C. or lower, the crystal grain size in the oxide sintered body can be reduced by suppressing the grain growth during sintering. The sintering temperature is more preferably 1,580° C. or lower, and still more preferably 1,550° C. or lower.

The retention time is not particularly limited as long as the sintering of the mixed powder proceeds sufficiently and the density of the obtained oxide sintered body becomes the predetermined density or more. For example, the retention time can be set at 1 to 5 hours.

If the retention time is 1 hour or more, the structure in the oxide sintered body to be obtained can be made uniform. The retention time is more preferably 2 hours or more, and still more preferably 3 hours or more. If the retention time is 5 hours or less, the grain growth during sintering can be suppressed and the crystal grain size in the oxide sintered body can be reduced. The retention time is more preferably 4 hours or less, and still more preferably 3 hours or less.

The average temperature rising rate is preferably 100° C./hour or less, and since abnormal growth of grains hardly occurs, the ratio of coarse grains can be suppressed. If the average temperature rising rate is 100° C./hour or less, the relative density of the oxide sintered body after sintering can be increased. The average temperature rising rate is more preferably 90° C./hour or less, and still more preferably 80° C./hour or less.

The lower limit of the average temperature rising rate is not particularly limited, and is preferably 50° C./hour or more, and more preferably 60° C./hour or more, from the viewpoint of the productivity.

The sintering atmosphere is preferably the air or an oxygen-rich atmosphere. In particular, it is desirable that the oxygen concentration in the atmosphere is 50 to 100 volume %.

As mentioned above, the oxide sintered body can be manufactured by the steps (a) to (e).

### (Step (f) of Processing the Oxide Sintered Body)

The thus obtained oxide sintered body may be processed into a shape suitable for a sputtering target. The method of processing the oxide sintered body is not particularly limited, and the oxide sintered body may be processed into a shape according to various applications by a known method.

### (Step (g) of Bonding the Oxide Sintered Body on a Backing Plate)

As shown in FIG. 1, the processed oxide sintered body 10 is bonded on a backing plate 20 using a bonding material 30. Whereby, a sputtering target 1 is obtained. The material of the backing plate 20 is not particularly limited, and is preferably pure copper or a copper alloy having excellent thermal conductivity. It is possible to use, as the bonding material 30, various known bonding materials having conductivity. For example, an In-based solder material, a Sn-based solder material and the like are suitable. The bonding method is not particularly limited as long as it is a method in which the backing plate 20 and the oxide sintered body 10 are bonded to each other using the bonding material 30. As an example, the oxide sintered body 10 and the backing plate 20 are heated to the temperature at which the bonding material 30 is melted (e.g., about 140° C. to about 220° C.). After applying the molten bonding material 30 to a bonding surface 23 of the backing plate 20 (the surface on which the oxide sintered body 10 is fixed, i.e., the upper surface of the backing plate 20), the oxide sintered body 10 is placed on the bonding surface 23. By cooling the backing plate 20 and the oxide sintered body 10 in a state of being press-contacted, the bonding material 30 is solidified, thereby fixing the oxide sintered body 10 on the bonding surface 23.

### EXAMPLES

The present invention will be more specifically described by way of Examples. It is to be understood that the present invention is not limited to the following Examples, and various design variations made in accordance with the purports mentioned hereinbefore and hereinafter are also included in the technical scope of the present invention.

### Example 1: Hot Pressing

### (Fabrication of Oxide Sintered Body)

A zinc oxide powder (ZnO) having a purity of 99.9.9%, an indium oxide powder (In₂ O₃) having a purity of 99.99%, a gallium oxide powder (Ga₂ O₃), having a purity of 99.99% and a tin oxide powder (SnO₂) having a purity of 99.99% were blended at atomic ratios (atomic %) shown in Table 1 to obtain raw material powders. Water and a dispersant (ammonium polycarboxylate) were added thereto, followed by mixing and pulverization in a ball mill for 20 hours. In this example, a ball mill using a nylon pod and using zirconia balls as media was used. Then, the mixed powder obtained in the above step was dried and granulated.

TABLE 1

| Component No. | [In] | [Ga] | [Zn] | [Sn] | [Zn]/[In] | [Sn]/[Ga] |
|---|---|---|---|---|---|---|
| a | 26 | 11 | 51 | 12 | 1.96 | 1.09 |
| b | 24 | 7 | 52 | 17 | 2.17 | 2.43 |
| c | 38 | 12 | 41 | 9 | 1.08 | 0.75 |

Using a die press, the mixed powder thus obtained was pressed under a pressure of 1.0 ton/cm² to fabricate a disc-shaped molded body having a diameter of 110 mm and a thickness of 13 mm. The molded body was heated to 500° C. under normal pressure in an air atmosphere and then degreased by retaining it at the same temperature for 5 hours. The degreased molded body was set in a graphite die and hot pressing was performed under the conditions shown in Table 2. At this time, N₂ gas was introduced into a furnace and then sintering was performed in an N₂ atmosphere.

TABLE 2

| | | | Average temperature | |
|---|---|---|---|---|
| | Sintering | Retention | rising rate to | |
| | temperature | time | sintering temperature | Surface pressure |
| | (° C.) | (hours) | (° C./hour) | (MPa) |
| A | 950 | 2 | 200 | 30 |
| B | 1,200 | 2 | 200 | 30 |
| C | 850 | 2 | 200 | 30 |

### (Measurement of Relative Density)

The relative density of the oxide sintered body was obtained using the porosity measured in the following manner.

An oxide sintered body prepared as a measuring sample is cut at any position in a thickness direction and the cut surface at any

TABLE 3

| | | Plane index | | | Intention |
|---|---|---|---|---|---|
| | ICDD Card No. | h | k | l | ratio to main peak |
| Zn₂SnO₄ | 74-2184 | 2 | 2 | 0 | 4.74 |
| InGaZnO₄ | 70-3625 | 1 | 0 | 10 | 2.55 |
| In₂O₃ | 71-2194 | 2 | 1 | 1 | 8.13 |
| SnO₂ | 71-0652 | 2 | 1 | 1 | 1.00 |
| InGaZn₂O₅ | 40-0252 | 0 | 0 | 6 | 3.33 |
| InGaZn₃O₆ | 40-0253 | 0 | 0 | 12 | 2.78 |

The content (volume ratio) of each crystal phase (Zn₂ SnO₄, InGaZnO₄, InGaZn₂ O₅, InGaZn₃ O₆ and In₂ O₃) was determined from the measured value I of the intensity of the selected peak according to the calculation formulas mentioned below. In the calculation formulas, the ratio of the intensity of the main peak of the target crystal phase to the sum (Iₛᵤₘ) of the intensities of the main peaks of six crystal phases can be obtained. In the present specification, the ratio of the intensity of the target crystal phase was taken as the content (%) of the crystal phase.

Ratio of intensity of main peak of Zn₂ SnO₄=content (%) of Zn₂ SnO₄=I[Zn₂ SnO₄]×4.74/Iₛᵤₘ×100(%)

Ratio of intensity of main peak of InGaZnO₄=content (%) of InGaZnO₄=I[InGaZnO₄]×2.55/Iₛᵤₘ×100(%)

Ratio of intensity of main peak of InGaZn₂ O₅=content (%) of InGaZn₂ O₅=I[InGaZn₂ O₅]×3.33/Iₛᵤₘ×100(%)

Ratio of intensity of main peak of InGaZn₃ O₆=content (%) of InGaZn₃ O₆=I[InGaZn₃O₆]×2.78/Iₛᵤₘ×100(%)

Ratio of intensity of main peak of In₂ O₃=content (%) of In₂ O₃=I[In₂ O₃]×8.13/Iₛᵤₘ×100(%)

Iₛᵤₘ=I[Zn₂ SnO₄]×4.74+I[InGaZnO₄]×2.55+I[In₂ O₃]×8.13+I[SnO₂]+I[InGaZn₂ O₅]×3.33+I[InGaZn₃ O₆]×2.78.

### (Average Crystal Grain Size)

“Average crystal grain size (μm)” of the oxide sintered body was measured in the following manner. First, an oxide sintered body prepared as a measuring sample was cut at any position in a thickness direction and the cut surface at any position is mirror-polished. Next, a photograph was taken at a magnification of 400 times using a scanning electron microscope (SEM). A straight line having a length of 100 μm was drawn in an arbitrary direction on the photograph thus taken, and the number (N) of grains existing on the straight line was determined. The value calculated from [100/N] (μm) was taken as “a crystal grain size on the straight line”. Furthermore, 20 straight lines each having a length of 100 μm were drawn on the photograph and the crystal grain sizes on the individual straight lines were calculated. In the case of drawing a plurality of straight lines, in order to avoid counting the same crystal grains plural times, straight lines were drawn so that the distance between adjacent straight lines became at least 20 μm (corresponding to the crystal grain size of coarse grains).

Then, the value calculated from [sum of the crystal grain sizes on the individual straight lines/20] was taken as “an average crystal grain size of the oxide sintered body”. The measurement results of the average crystal grain size are shown in Table 2.

### (Cracking During Bonding)

Regarding the oxide sintered body, it was examined whether cracking occurred when bonding on a backing plate using a bonding material.

After the machined oxide sintered body was bonded on the backing plate under the above conditions, it was visually confirmed whether cracking occurred on the surface of the oxide sintered body. When cracking exceeding 1 mm in length was observed on the surface of the oxide sintered body, it was judged that “cracking occurred”, whereas, when cracking exceeding 1 mm in length could not be confirmed, it was judged that “cracking did not occur”.

For the respective Examples and Comparative Examples, ten machined oxide sintered bodies were prepared and the operation of bonding on the backing plate was performed ten times. When “cracking occurred” even in one oxide sintered body, the column of “Cracking” in Table 4 was filled with “Occurred”. When “cracking did not occur” in all ten sheets, the column of “Cracking” in Table 4 was filled with “None”.

TABLE 4

| | | | | | | | | | | | | Average | |
|---|---|---|---|---|---|---|---|---|---|---|---|---|---|
| | | | | | | | | | | | | crystal | |
| | | | | | Relative | | | | | | | grain | |
| | Component | Firing | [Zn]/ | [Sn]/ | density | Crystal phase (volume %) | | | | | | size | |
| | No. | conditions | [In] | [Ga] | (%) | Zn₂SnO₄ | InGaZnO₄ | InGaZn₂O₅ | InGaZn₃O₆ | In₂O₃ | SnO₂ | (μm) | Cracking |
| Example 1 | a | A | 1.96 | 1.09 | 99 | 48 | 12 | 18 | 2 | 20 | 0 | 3 | None |
| Example 2 | b | B | 2.17 | 2.43 | 99 | 68 | 11 | 5 | 1 | 15 | 0 | 4 | None |
| Example 3 | c | C | 1.08 | 0.75 | 99 | 32 | 20 | 13 | 5 | 30 | 0 | 3 | None |

In Examples 1 to 3 in which the relative density and the content of the crystal phase are within the range defined in the embodiment of the present invention, cracking did not occur when the oxide sintered body was bonded on the backing plate.

### Example 2: Pressureless Sintering

In the same manner as in Example 1, raw material powders a to c shown in Table 1 were prepared.

Using a die press, the mixed powder thus obtained was pressed under a pressure of 1.0 ton/cm² to fabricate a disc-shaped molded body having a diameter of 110 mm and a thickness of 13 mm. The molded body was heated to 500° C. under normal pressure in an air atmosphere and then degreased by retaining it at the same temperature for 5 hours. The degreased molded body was set in a graphite die and hot pressing was performed under the conditions shown in Table 5. At this time, N₂ gas was introduced into a furnace and then sintering was performed in an N₂ atmosphere.

TABLE 5

| | | | Average temperature |
|---|---|---|---|
| | Sintering | Retention | rising rate to |
| | temperature | time | sintering temperature |
| | (° C.) | (hours) | (° C./hour) |
| I | 1,550 | 2 | 50 |
| II | 1,500 | 2 | 50 |
| III | 1,400 | 2 | 50 |

In the same manner as in Example 1, the oxide sintered body thus obtained was subjected to the measurement of the measurement of the relative density, the content of the crystal phase, the average crystal grain size and cracking during bonding. The measurement results are shown in Table 6 and Table 7.

TABLE 6

| | | | | | | | | | | | | Average | |
|---|---|---|---|---|---|---|---|---|---|---|---|---|---|
| | | | | | | | | | | | | crystal | |
| | | | | | Relative | | | | | | | grain | |
| | Component | Firing | [Zn]/ | [Sn]/ | density | Crystal phase (volume %) | | | | | | size | |
| | No. | conditions | [In] | [Ga] | (%) | Zn₂SnO₄ | InGaZnO₄ | InGaZn₂O₅ | InGaZn₃O₆ | In₂O₃ | SnO₂ | (μm) | Cracking |
| Example 5 | a | I | 1.96 | 1.09 | 98 | 48 | 14 | 17 | 0 | 21 | 0 | 20 | None |
| Example 6 | a | II | 1.96 | 1.09 | 96 | 46 | 12 | 18 | 1 | 23 | 0 | 15 | None |
| Example 7 | b | I | 2.17 | 2.43 | 96 | 67 | 9 | 6 | 0 | 18 | 0 | 20 | None |
| Com- | a | III | 1.96 | 1.09 | 91 | 46 | 11 | 19 | 0 | 24 | 0 | 10 | Occurred |
| parative | | | | | | | | | | | | | |
| Example 1 | | | | | | | | | | | | | |

TABLE 7

| | | | | | | | | | | | | Average | |
|---|---|---|---|---|---|---|---|---|---|---|---|---|---|
| | | | | | | | | | | | | crystal | |
| | | | | | Relative | | | | | | | grain | |
| | Component | Firing | [Zn]/ | [Sn]/ | density | Crystal phase (volume %) | | | | | | size | |
| | No. | conditions | [In] | [Ga] | (%) | Zn₂SnO₄ | InGaZnO₄ | InGaZn₂O₅ | InGaZn₃O₆ | In₂O₃ | SnO₂ | (μm) | Cracking |
| Example 8 | c | I | 1.08 | 0.75 | 97 | 0 | 5 | 16 | 0 | 79 | 0 | 12 | None |

In Examples 5 to 8 in which the relative density is within the range defined in the embodiment of the present invention, cracking did not occur when the oxide sintered body was bonded on the backing plate.

In Comparative Example 1, since the density was as low as 91%, cracking occurred when the oxide sintered body was bonded on the backing plate.

The present disclosure includes the following aspects.

### Aspect 1:

An oxide sintered body, wherein contents of zinc, indium, gallium and tin relative to all metal elements satisfy the following inequality expressions:

40 atomic %≤[Zn]≤55 atomic %,

20 atomic %≤[In]≤40 atomic %,

5 atomic %≤[Ga]≤15 atomic %, and

5 atomic %≤[Sn]≤20 atomic %,

where the contents (atomic %) of zinc, indium, gallium and tin relative to all metal elements excluding oxygen are respectively taken as [Zn], [In], [Ga] and [Sn],

wherein the oxide sintered body has a relative density of 95% or more, and

wherein the oxide sintered body includes, as a crystal phase, 5 to 20 volume % of InGaZn₂ O₅.

### Aspect 2:

The oxide sintered body according to aspect 1, wherein pores in the oxide sintered body have a maximum equivalent circle diameter of 3 μm or less.

### Aspect 3:

The oxide sintered body according to aspect 1 or 2, wherein a relative ratio of an average equivalent circle diameter (μm) to the maximum equivalent circle diameter (μm) of pores in the oxide sintered body is 0.3 or more and 1.0 or less.

### Aspect 4:

The oxide sintered body according to any one of aspects 1 to 3, wherein [Zn]/[In] is more than 1.75 and less than 2.25, and

the oxide sintered body further includes, as a crystal phase:

30 to 90 volume % of Zn₂ SnO₄, and

1 to 20 volume % of InGaZnO₄.

### Aspect 5:

The oxide sintered body according to any one of aspects 1 to 3, wherein [Zn]/[In] is less than 1.5, and

the oxide sintered body further includes, as a crystal phase, 30 to 90 volume % of In₂ O₃.

### Aspect 6:

The oxide sintered body according to any one of aspects 1 to 3, further including, as a crystal phase, more than 0 volume % and 10 volume % or less of InGaZn₃ O₆.

### Aspect 7:

The oxide sintered body according to any one of aspects 1 to 6, wherein a crystal grain size in the oxide sintered body is 20 μm or less.

### Aspect 8:

The oxide sintered body according to aspect 7, wherein the crystal grain size is 5μμ or less.

### Aspect 9:

The oxide sintered body according to any one of aspects 1 to 8, wherein a resistivity of the oxide sintered body is 1 Ω·cm or less.

### Aspect 10:

A sputtering target including a backing plate and the oxide sintered body of any one of aspects 1 to 9 fixed on the backing plate using a bonding material.

### Aspect 11:

A method for manufacturing the oxide sintered body of any one of aspects 1 to 9, the method including:

preparing a mixed powder containing zinc oxide, indium oxide, gallium oxide and tin oxide at a predetermined ratio, and sintering the mixed powder into a predetermined shape.

### Aspect 12:

The manufacturing method according to aspect 11, the step of sintering includes retaining the mixed powder at a sintering temperature of 900 to 1,100° C. for 1 to 12 hours in a state of applying a surface pressure of 10 to 39 MPa to the mixed powder in a mold.

### Aspect 13:

The manufacturing method according to aspect 12, wherein an average temperature rising rate to the sintering temperature is 600° C./hour or less in the step of sintering.

### Aspect 14:

The manufacturing method according to aspect 11, further including preforming the mixed powder after the step of preparing the mixed powder and before the step of sintering,

wherein the step of sintering includes retaining a preformed molded body at a sintering temperature of 1,450 to 1,550° C. for 1 to 5 hours under normal pressure.

### Aspect 15:

The manufacturing method according to aspect 14, wherein an average temperature rising rate to the sintering temperature is 100° C./hour or less in the step of sintering.

### Aspect 16:

A method for manufacturing a sputtering target, the method including: bonding the oxide sintered body of any one of aspects 1 to 9 or the oxide sintered body obtained by the manufacturing method of any one of aspects 11 to 15 on a backing plate using a bonding material.

This application claims priority based on Japanese Patent Application No. 2016-83840 filed on Apr. 19, 2016 and Japanese Patent Application No. 2017-7850 filed on Jan. 19, 2017, the disclosures of which are incorporated by reference herein.

### DESCRIPTION OF REFERENCE NUMERALS

1 Sputtering target
10 Oxide sintered body
20 Backing plate
30 Bonding material

1.-16. (canceled)

17. An oxide sintered body, comprising:
40 atomic %≤[Zn]≤55 atomic %,
20 atomic %≤[In]≤40 atomic %,
5 atomic %≤[Ga]≤15 atomic %, and
5 atomic %≤[Sn]≤20 atomic %,
where contents of zinc, indium, gallium and tin relative to all metal elements excluding oxygen are respectively taken as [Zn], [In], [Ga] and [Sn],
the oxide sintered body has a relative density of 95% or more,
a ratio of [Zn]/[In] is less than 1.5, and
the oxide sintered body comprises, as a crystal phase, from 5 to 20 volume % of InGaZn₂ O₅ and from 30 to 90 volume % of In₂ O₃.

18. The oxide sintered body of claim 17, wherein pores in the oxide sintered body have a maximum equivalent circle diameter of 3 μm or less.

19. The oxide sintered body of claim 17, wherein a relative ratio of an average equivalent circle diameter to a maximum equivalent circle diameter of pores in the oxide sintered body is 0.3 or more and 1.0 or less.

20. The oxide sintered body of claim 17, further comprising, as a crystal phase, more than 0 volume % and 10 volume % or less of InGaZn₃ O₆.

21. The oxide sintered body of claim 17, wherein a crystal grain size in the oxide sintered body is 20 μm or less.

22. The oxide sintered body of claim 21, wherein the crystal grain size is 5 μm or less.

23. The oxide sintered body of claim 17, wherein a resistivity of the oxide sintered body is 1 Ω·cm or less.

24. A sputtering target, comprising a backing plate and the oxide sintered body of claim 17 fixed on the backing plate with a bonding material.

25. A method for manufacturing the oxide sintered body of claim 17, the method comprising:
preparing a mixed powder comprising zinc oxide, indium oxide, gallium oxide and tin oxide at a predetermined ratio, and
sintering the mixed powder into a predetermined shape.

26. The method of claim 17, further comprising:
retaining the mixed powder at a sintering temperature of from 900 to 1,100° C. for 1 to 12 hours in a state of applying a surface pressure of from 10 to 39 MPa to the mixed powder in a mold.

27. The method of claim 26, wherein the sintering comprises sintering at an average temperature rising rate to the sintering temperature of 600° C./hour or less.

28. The manufacturing method of claim 25, further comprising:
preforming the mixed powder after the preparing the mixed powder and before the sintering,
wherein the sintering comprises retaining a preformed molded body at a sintering temperature of 1,450 to 1,550° C. for 1 to 5 hours under normal pressure.

29. The method of claim 28, wherein the sintering comprises sintering at an average temperature rising rate to the sintering temperature of 100° C./hour or less.

30. A method for manufacturing a sputtering target, the method comprising:
bonding the oxide sintered body of claim 17 on a backing plate using a bonding material.

31. A method for manufacturing a sputtering target, the method comprising:
bonding an oxide sintered body obtained by the method of claim 25 on a backing plate using a bonding material.
